(19) United States
(12) Patent Application Publication
(10) Pub. No.: US 2025/0151460 A1
(43) Pub. Date: May 8, 2025

(54) SEMICONDUCTOR STRUCTURE

(71) Applicant: EPISTAR CORPORATION, Hsinchu (TW)

(72) Inventors: Yung-Chung PAN, Hsinchu (TW); Ming-Pao CHEN, Hsinchu (TW); Peng-Ren CHEN, Hsinchu (TW)

(21) Appl. No.: 18/930,694

(22) Filed: Oct. 29, 2024

(30) Foreign Application Priority Data
Nov. 2, 2023 (TW) 112142200
Sep. 27, 2024 (TW) 113137106

(51) Int. Cl. H01L 33/06; H01L 33/12; H01L 33/32

(52) U.S. Cl. CPC H10H 20/812; H10H 20/815; H10H 20/825

(57) ABSTRACT

A semiconductor structure includes a first semiconductor stack having a first conductivity type, a second semiconductor stack having a second conductivity type, an active structure disposed between the first semiconductor stack and the second semiconductor stack, and an aluminum-containing cap layer in the active structure. The active structure includes a plurality of group III nitride barrier layers and a plurality of group III-nitride quantum well layers which are alternately stacked. The thickness of the group III-nitride barrier layers is ranged between 200 angstroms to 550 angstroms, and the aluminum-containing cap layer is disposed between the group III nitride quantum well layers and the group III nitride barrier layers, and the active structure has a wavelength of at least 600 nm.

### RELATED APPLICATIONS

This application claims priority to the benefit of Taiwan Patent Application Number 112142200 filed on Nov. 2, 2023 and Taiwan Patent Application Number 113137106 filed on Sep. 27, 2024, the entire contents of which are hereby incorporated by reference herein in their entireties.

### TECHNICAL FIELD

The present disclosure relates to a semiconductor structure, and more particularly, to a semiconductor structure of a light-emitting diode.

### DESCRIPTION OF BACKGROUND ART

Light-emitting diode (LED) has advantages of low power consumption, low generated heat, long working life, shockproof, small size, and rapid response. Therefore, they are widely applied to electronic equipment, such as vehicles, household appliances, equipment indicators, and luminating lamp. Particularly, LEDs can emit monochromatic light, which can be used as pixels of display and provide excellent contrast and color saturation. However, the present LED display still have some issues to be solved, such as optoelectronic characteristics mismatch of red light, green light, and blue light LED chips.

### SUMMARY OF THE APPLICATION

In view of this, embodiments of the present disclosure provide a group III nitride quantum well structure of a semiconductor structure, which can effectively enhance the light-emitting efficiency of the semiconductor structure and reduce the blue shift phenomenon and the FWHM of the light-emitting wavelength under the condition that the light-emitting wavelength is greater than 600 nm.

According to an embodiment of the present disclosure, a semiconductor structure comprising a first semiconductor stack, a second semiconductor stack, an active structure, and an aluminum-containing cap layer is provided. The first semiconductor stack has first conductivity type and the second semiconductor stack has second conductivity type. The active structure is disposed between the first semiconductor stack and the second semiconductor stack and comprises plural group III nitride barrier layers and plural group III nitride quantum well layers that are alternately stacked. Each of the group III nitride barrier layers has a thickness ranged from 200 angstroms to 550 angstroms. The aluminum-containing cap layer is disposed in the active structure and disposed between one of the aforementioned group III nitride quantum well layers and one of the aforementioned group III nitride barrier layers. Such group III nitride barrier layer is disposed on and adjacent to such group III nitride quantum well layer. The active structure emits light with a wavelength greater than 600 nm.

According to another embodiment of the present disclosure, a semiconductor structure comprising a first semiconductor stack, a second semiconductor stack, an active structure, a pre-strain stack, and an aluminum-containing interlayer is provided. The first semiconductor stack has first conductivity type, and the second semiconductor stack has second conductivity type. The active structure is disposed between the first semiconductor stack and the second semiconductor stack and comprises plural group III nitride barrier layers and plural group III nitride quantum well layers that are alternately stacked. The pre-strain stack is disposed between the first semiconductor stack and the active structure and comprises plural first sublayers and plural second sublayers that are alternately stacked. The aluminum-containing interlayer is disposed in/on the pre-strain stack. The active structure emits light with a wavelength greater than 600 nm.

### BRIEF DESCRIPTION OF THE DRAWINGS

Aspects of the present disclosure are better understood from the following detailed description when read with the accompanying figures. Through the specific embodiments and the corresponding figures of the disclosure, the detail of the specific embodiments and the action principles of the present disclosure are thus better illustrated. In addition, for the sake of clarity, the features of each of the figures may not be drawn in accordance with practical scale. The size of some of the features in the figures may be deliberately scaled up or down, wherein:

FIG. 1 illustrates a cross-sectional schematic view of a semiconductor structure in accordance with an embodiment of the present disclosure;

FIG. 2 illustrates another cross-sectional schematic view of a semiconductor structure in accordance with an embodiment of the present disclosure;

FIG. 3 illustrates a cross-sectional schematic view of a light-emitting element in accordance with an embodiment of the present disclosure;

FIG. 4 illustrates a cross-sectional schematic view of a light-emitting structure in accordance with an embodiment of the present disclosure;

FIG. 5 illustrates another cross-sectional schematic view of a light-emitting device in accordance with an embodiment of the present disclosure;

FIG. 6 illustrates a curve chart of external quantum efficiency changed with the current density of the light-emitting element in accordance with the embodiment of the present disclosure;

FIG. 7 illustrates a wavelength curve chart changed with the current density of the light-emitting element in accordance with the embodiment of the present disclosure;

FIG. 8 illustrates an initiating voltage curve chart changed with the current density of the light-emitting element in accordance with the embodiment of the present disclosure;

FIG. 9 illustrates a luminous intensity curve chart versus the wavelength of the light-emitting element changed with the current density in accordance with the embodiment of the present disclosure;

FIG. 10 illustrates a cross-sectional schematic view of a semiconductor structure in accordance with an embodiment of the present disclosure;

FIG. 11 illustrates schematic views of analysis results of destructive physical analysis of the pre-strain stack of an embodiment of the present disclosure and the comparative embodiment;

FIG. 12 illustrates a schematic view illustrating analytic result of X-ray diffraction analysis of the pre-strain stack of the embodiment of the present disclosure and the comparative embodiment;

FIG. 13 illustrates a cross-sectional schematic view of a light-emitting structure in accordance with an embodiment of the present disclosure;

FIG. 14 illustrates a schematic spectrum chart of a light-emitting element changed with the current of an embodiment of the present disclosure; and

FIG. 15 illustrates wavelength peak tendency chart and wavelength FWHM tendency chart produced in accordance with FIG. 14.

### DETAILED DESCRIPTION OF THE APPLICATION

Different embodiments of the present disclosure are provided to accomplish different features of the present disclosure. It should be understood that in the following detailed description, for purposes of explanation, numerous specific details and embodiments are set forth to provide a thorough understanding of the present disclosure. The elements and configurations described in the following detailed description are set forth to clearly describe the present disclosure. The embodiments are used merely for the purpose of illustration. In addition, the drawings of different embodiments may use the same numerals to denote like and/or corresponding elements in order to clearly describe the present disclosure. However, the use of like and/or corresponding numerals in the drawings of different embodiments does not suggest any correlation between different embodiments.

Further, spatially relative terms, such as “beneath,” “below,” “lower,” “over,” “above,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. For example, if the semiconductor device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or manufacturing order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified. all of the numerical ranges, amounts, values and percentages disclosed herein should be understood as modified in all instances by the term “about” or “substantial” Accordingly, unless indicated to the contrary, the numerical parameters set forth in the present disclosure and attached claims are approximations that can vary as desired.

In the description of the embodiments of the present disclosure,

the terms “coupling” and “electric connection” may comprise any direct or indirect electric connection. For instance, if the document describes the first object is coupled to a second object, it means the first object may be directly electrically connected with the second object or indirectly electrically connected to the second object via other device or connecting means.

Although the present disclosure below is described through specific embodiments, the inventive principles may also be applied to other embodiments. In addition, in order not to obscure the spirit of the present invention, specific details may be omitted, and these omitted details fall within the scope of knowledge of those with ordinary skill in the art.

In the present disclosure, if not otherwise specified, the general formula AlGaN represents the material of AlₐGa₍₁₋ₐ₎N, wherein 0≤a≤1; the general formula InGaN represents the material of In_{b}Ga_{(1-b)}N, wherein 0≤b≤1; the general formula AlGaInP represents the material of Al_{c}Ga_{d}In_{(1-c-d)}P, wherein 0≤c≤1 and 0≤d≤1. The content of each element may be adjusted for different purposes, for example, for adjusting the energy gap, or the main light-emitting wavelength of a light-emitting structure.

The composition, dopants, and dopant concentration contained in each layer of the semiconductor structure may be analyzed by any suitable method, such as a secondary ion mass spectrometer (SIMS).

The thickness of each layer may be analyzed by any suitable method, such as a transmission electron microscopy (TEM) or a scanning electron microscope (SEM) combined with the positions of the thickness of each layer shown in SIMS.

In an embodiment of the present application, the forming method of the semiconductor stack comprises metal organic chemical vapor deposition (MOCVD), hydride vapor phase epitaxy (HVPE), molecular beam epitaxy (MBE), physical vapor deposition (PVD), or liquid-phase epitaxy (LPE). In the following embodiments, the forming method of the semiconductor structure is set forth, e.g., by MOCVD.

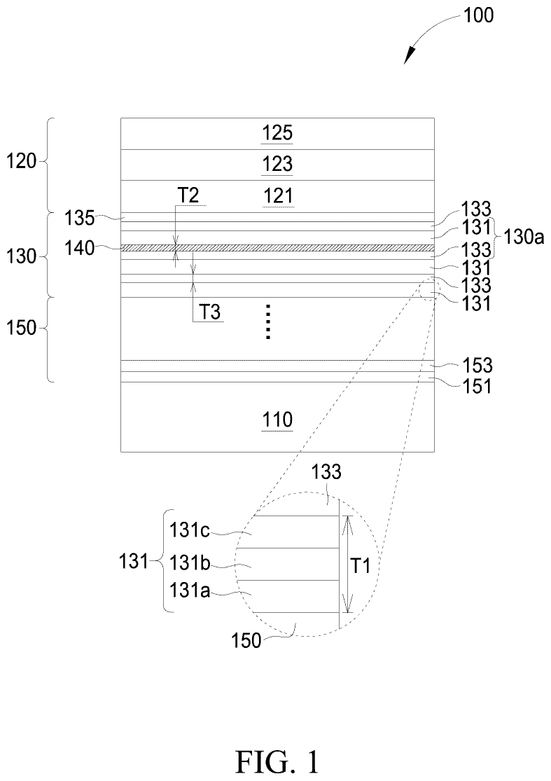

FIG. 1 shows a cross-sectional schematic view of a semiconductor structure 100 in accordance with an embodiment of the present disclosure. The semiconductor structure 100 comprises plural group III nitride semiconductor layers that are sequentially stacked. The group III element may be Al, Ga, or In, and the group III nitride semiconductor layers may be a binary, ternary, or quaternary semiconductor compound represented by AlₓIn_{y}Ga_{(1-x-y)}N, wherein 0≤x≤1, 0≤y≤1, and (x+y)≤1, such as gallium nitride, aluminum gallium nitride, indium gallium nitride, or indium aluminum gallium nitride. In addition, according to practical need of the semiconductor device, the group III nitride semiconductor layers may optionally comprise dopants to become n-type or p-type group III nitride semiconductor layers. The n-type dopants may comprise Si, while the p-type dopants may comprise Mg.

Firstly, as shown in FIG. 1, the semiconductor structure 100 comprises a first semiconductor stack 110 having first conductivity type, a second semiconductor stack 120 having second conductivity type, and an active structure 130 disposed between the first semiconductor stack 110 and the second semiconductor stack 120. The first semiconductor stack 110 and the second semiconductor stack 120 may be served as confinement layers, carrier supply layers, or contact layers of the semiconductor structure 100. The first semiconductor stack 110 and the second semiconductor stack 120 may comprise different doping types of semiconductor material to supply carriers, such as electrons or holes. For instance, the first semiconductor stack 110 may comprise n-type semiconductor layer and the second semiconductor stack 120 may comprise p-type semiconductor layer to supply electrons and holes respectively. Alternatively, the first semiconductor stack 110 comprises p-type semiconductor layer and the second semiconductor stack 120 comprises n-type semiconductor layer to supply holes and electrons respectively. The first semiconductor stack 110 and the second semiconductor stack 120 may be deliberately doped or non-deliberately doped to have first conductivity or second conductivity respectively to provide the corresponding carriers to the active structure 130.

The active structure may serve as a light-emitting structure, so the semiconductor structure 100 may be applied to a light-emitting element and the wavelength of the emitted light of the light-emitting element depends on the material composition of the active structure 130. Specifically, the active structure 130 may comprise group III nitride materials, such as InGaN series material, AlGaN series material or AlInGaN series material. When the active structure 130 comprises the InGaN series material, red light having a wavelength essentially ranged between 570 nm and 650 nm or between 620 nm to 630 nm, or green light having a wavelength essentially ranged between 530 nm and 570 nm can be emitted. When the active structure 130 comprises InGaN series materials, blue light having a wavelength ranged between 400 nm and 490 nm, cyan light having a wavelength ranged between 490 nm and 530 nm, or green light having a wavelength essentially ranged between 530 nm to 570 nm can be emitted. When the active structure 130 comprises AlInGaN series materials, AlGaN series materials or AlBGaN series materials, UV light having a wavelength ranged between 250 nm and 400 nm can be emitted. In some embodiment, the active structure 130 may comprise a single heterostructure, a double heterostructure, a single quantum well structure, or a multiple quantum well structure (MQW). In some embodiment, the material of the active structure 130 may be i-type, p-type, or n-type semiconductor. In the embodiment that the active structure 130 is a multiple quantum well structure, it comprises one or more group III nitride barrier layers 131 and one or more group III nitride quantum well layers 133 by one time or multiple times alternate stacking. In some embodiment, the group III nitride barrier layer 131 may be served as a first layer of the active structure 130, and/or the group III nitride barrier layers 131 may be served as a last layer. In another embodiment, the group III nitride quantum well layer 133 may be served as the first layer of the active structure 130, and/or the group III nitride quantum well layer 133 may be served as the last layer. One of the group III nitride quantum well layer 133 and one of the group III nitride barrier layer 131 can constitute a quantum well structure pair 130a. In one embodiment, the group III nitride barrier layer 131 may comprise nitride materials, such as gallium nitride or aluminum gallium nitride having the chemical composition formula Alₓ₁Ga₁₋ₓ₁N, wherein 0≤x1≤0.3. In another embodiment, x1 is in the range of 0≤x1≤0.3. The group III nitride quantum well layer 133 comprises indium gallium nitride materials having the composition formula Inₓ₂GaN, wherein 0≤x2≤0.45. In another embodiment, x2 may be in the range of 0≤x2≤0.35 or in the range of 0.18≤x2≤0.35. Group III nitride quantum well layer 133 and group III nitride barrier layer 131 may optionally have appropriate dopants, such as n-type dopants or have no dopant.

In one embodiment, the active structure 130 may further comprise a top barrier layer 135 disposed in the active structure 130 and adjacent to the second semiconductor stack 120. In one embodiment, the semiconductor structure 100 further comprises one aluminum-containing cap layer 140 disposed on any one of the group III nitride quantum well layer 133 of the quantum well structure pairs 130a. That is, when the quantum well structure pairs 130a are formed by sequential stacking by the group III nitride barrier layer 131 and the group III nitride quantum well layer 133 formed thereon, as shown in FIG. 1, the aluminum-containing cap layer 140 covers one of the group III nitride quantum well layer 133 of the quantum well structure pairs 130a, and the group III nitride barrier layer 131, which may be another group III nitride barrier layer 131 not belong to the aforementioned one of the quantum well structure pairs 130a may be disposed below the aluminum-containing cap layer 140. The aforementioned another group III nitride barrier layer 131 over the aluminum-containing cap layer 140 may belong to the group III nitride barrier layer 131 of another quantum well structure pair 130a or belong to the last group III nitride barrier layer 131 in the active structure 130. In another embodiment, when the quantum well structure pairs (not shown in the figures) are formed by sequential stacking the group III nitride quantum well layer 133 and the group III nitride barrier layer 131 formed thereon, at this time, the aluminum-containing cap layer 140 is disposed between the group III nitride quantum well layer 133 and the group III nitride barrier layer 131 of the quantum well structure pairs. The aluminum-containing cap layer 140 may be a part of the active structure 130, and the aluminum-containing cap layer 140 covers the group III nitride quantum well layer 133. The energy gap of the aluminum-containing cap layer 140 may be greater than the energy gap of the group III nitride barrier layer 131, and the energy gap of the group III nitride barrier layer 131 is greater than the energy gap of the group III nitride quantum well layer 133. The aluminum composition ratio of the aluminum-containing cap layer 140 is greater than the aluminum composition ratio of the group III nitride barrier layer 131. The lattice constant of the material constituting the aluminum-containing cap layer 140 is less than the lattice constant of the material constituting the group III nitride barrier layer 131. The lattice constant of the material constituting the aluminum-containing cap layer 140 is less than the lattice constant of the material constituting the group III nitride quantum well layer 133. In one embodiment, the aluminum-containing cap layer 140 is disposed between the group III nitride barrier layer 131 and the group III nitride quantum well layer 133 in the active structure 130, by means of the tensile strain and the compressive strain caused by the lattice difference among the aforementioned three layers, strain compensation can be generated to further improve the strain effect of the multiple quantum well structure and reduce its structural defect.

In one embodiment, the film of the aluminum-containing cap layer 140 can have high density feature so the aluminum-containing cap layer 140 can serve as a protective layer of the group III nitride quantum well layer 133 to prevent uneven distribution of group III elements (e.g., indium) when the group III nitride quantum well layer 133 is grown in the subsequent high temperature growth environment. For instance, the partial accumulation of indium element may form quantum dots structure or cause the desorption of indium element from the group III nitride quantum well layer 133. Under the protection of the aluminum-containing cap layer 140, the indium content (In %) inside the group III nitride quantum well layer 133 can be sustained and evenly distributed. In one embodiment, under the condition that the active structure 130 comprising the aluminum-containing cap layer 140, since the aluminum-containing cap layer 140 has higher energy gap, it can confine the carriers in the active structure 130. Even under the condition that the thickness T1 of the group III nitride barrier layer 131 is reduced, the active structure 130 can still maintain the external quantum efficiency (EQE), therefore the light-emitting intensity of the light-emitting element constituted by the semiconductor structure 100 can be maintained.

The structures of the aluminum-containing cap layer 140 and the group III nitride quantum well layer 133 of the active structure 130 may be adjusted in accordance with user's need. In consideration of improving the epitaxial quality of the active structure 130, the aluminum-containing cap layer 140 can improve the group III nitride quantum well layer 133 to sustain high compressive strain effect, and then the group III-nitride barrier layer 131 can adjust the tensile strain of the aluminum-containing cap layer 140 to further improve the epitaxial quality of the active structure 130. In addition, the thickness of the aluminum-containing cap layer 140 can be further adjusted to alleviate the impact of epitaxial quality caused by the increasement of the thickness of the aluminum-containing cap layer 140 having high aluminum composition ratio and alleviate the hinder of the injection of the carriers caused by the aluminum-containing cap layer 140 that has high aluminum composition ratio with high energy gap and has a thickness greater than a certain thickness. In one embodiment, the aluminum-containing cap layer 140 comprises nitride materials, such as aluminum nitride or aluminum gallium nitride, which have a chemical composition formula represented by Alₓ₃Ga₁₋ₓ₃N, wherein 0.5≤x3≤1. The aluminum content (Al %) of the aluminum-containing cap layer 140 may be further increased to 80% approximately, benefiting the active structure 130 to maintain the indium content in the group III nitride quantum well layer 133 to further render the light-emitting wavelength of the emitted light from the active structure 130 moving toward a longer wavelength range to improve the blue shift phenomenon and provide strain compensation. As mentioned above, the aluminum-containing cap layer 140 can have a greater degree of freedom to achieve the effect of strain compensation by adjusting the thickness and aluminum content of the aluminum-containing cap layer 140. Under the condition of considering the epitaxial quality of the aluminum-containing cap layer 140 along with the impact to the injection of the carriers and the protective effect to the group III nitride quantum well layer 133, the thickness of aluminum-containing cap layer 140 may be further adjusted or limited. In one embodiment, the thickness T2 of the aluminum-containing cap layer 140 may be ranged between 15 angstroms to 35 angstroms, 15 angstroms to 30 angstroms, or between 15 angstroms to 25 angstroms, e.g., 23 angstroms, 25 angstroms or 27 angstroms. Therefore, the indium content of the active structure 130 can be maintained at the predetermined composition ratio to render the light-emitting wavelength being greater than 600 nanometers under the condition of good light-emitting intensity and good light-emitting efficiency.

The group III nitride barrier layer 131 can provide the function of preventing carriers overflow and compensate the strain caused by the aluminum-containing cap layer 140. The material and the thickness of the aluminum-containing cap layer 140 may be adjusted in accordance with the structure of the aluminum-containing cap layer 140 and the group III nitride quantum well layer 133. In one embodiment, when the thickness of the aluminum-containing cap layer 140 is fixed and the aluminum composition ratio of the aluminum-containing cap layer 140 is greater than 50%, the thickness T1 of the group III nitride barrier layer 131 can be increased with the increasement of the aluminum composition ratio of the aluminum-containing cap layer 140. In other embodiment, the epitaxial growth condition of the group III nitride barrier layer 131 can be adjusted by, e.g., the temperature, the pressure or the thickness to adjust the film quality of the group III nitride barrier layer 131. Therefore, the thickness T1 of the group III nitride barrier layer 131 can be adjusted, e.g., increasing or decreasing, to a specific thickness, so that the strain compensation effect for the aluminum-containing cap layer 140 having high aluminum content can be achieved with a thinner thickness T1. The thickness T2 of the aluminum-containing cap layer 140 is less than the thickness T1 of the group III nitride barrier layer 131. The thickness T1 of the group III nitride barrier layer 131 is ranged, e.g., between 200 angstroms and 550 angstroms, between 250 angstroms and 340 angstroms, e.g., 260 angstroms, 270 angstroms, or 340 angstroms. In another embodiment, the thickness T1 of the group III nitride barrier layer 131 is ranged between 100 angstroms and 200 angstroms. Alternatively, in other embodiment, by increasing the band gap of the group III nitride barrier layer 131, the thickness T1 of the group III nitride barrier layer 131 can be further lessened. In one embodiment, the band gap of the group III nitride barrier layer 131 can be increased by increasing its aluminum content. The method of adjusting the aluminum content can be achieved by adjusting the growth condition of the group III nitride barrier layer 131. Taking epitaxial growth by MOCVD as an example, the aluminum content of the group III nitride barrier layer 131 can be increased by, e.g., decreasing the epitaxial growth pressure or decreasing the epitaxial growth speed. The thickness T1 of the group III nitride barrier layer 131 may be ranged between 50 angstroms and 150 angstroms, e.g., 50 angstroms, 100 angstroms or 150 angstroms. By additionally providing one layer of aluminum-containing cap layer 140 in the active structure 130 to provide strain compensation and provide a protective layer for the multiple quantum well structure, the strain effect and structural defect of the active structure 130 can be effectively improved. The carrier recombination efficiency in the active structure 130 can be also enhanced to enhance the light-emitting efficiency of the semiconductor structure 100.

In addition, the thickness T3 of the group III nitride quantum well layer 133 is less than the thickness T1 of the group III nitride barrier layer 131. For instance, the thickness T3 may be ranged between 30 angstroms to 45 angstroms, such as 34 angstroms or 38 angstroms. The thickness of the top barrier layer 135 is also less than the thickness T1 of the group III nitride barrier layer 131 each. The thickness of the top barrier layer 135 is ranged between 10 angstroms and 50 angstroms, such as 20 angstroms, 26 angstroms or 30 angstroms. In one embodiment, the top barrier layer 135 may comprise n-type dopants. The concentration of the n-type dopants may be ranged between 1E17/cm³ and 1E18/cm³.

In another embodiment, the quantity of the quantum well structure pairs 130a constituted by the group III nitride barrier layers 131 and the group III nitride quantum well layers 133 may have a quantity ranged between 2 pairs to 5 pairs, such as 3 pairs. The indium content of the group III nitride quantum well layer 133 may be accordingly increased to be ranged between 20% to 40%, such as 22% or 30% when at least one aluminum-containing cap layer 140 is further provided. Therefore, the increasement of the indium content of the group III nitride quantum well layer 133 can accordingly increase the wavelength of the emitted light from the active structure 130. For instance, the wavelength can be increased to be more than 600 nm, such as 602 nm or 618 nm. In addition, the group III nitride barrier layer 131 may further comprise plural sublayers, e.g., first sublayer 131a, second sublayer 131b, and third sublayer 131c. The lattice constant of the first sublayer 131a and/or the lattice constant of third sublayer 131c, compared to the lattice constant of the second sublayer 131b, is closer to the lattice constant of the group III nitride quantum well layer 133. The lattice constant of the second sublayer 131b is less than the lattice constant of the first sublayer 131a and/or the lattice constant of the third sublayer 131c. In another embodiment, the lattice constant of the first sublayer 131a, the lattice constant of the second sublayer 131b, and the lattice constant of the third sublayer 131c are the same. In one embodiment, the material of the first sublayer 131a and the third sublayer 131c are the same, e.g., GaN or InGaN. The material of the second sublayer 131b may comprise GaN, AlN, AlGaN, AlInN, or AlInGaN. In one embodiment, the group III nitride barrier layers 131 each in the active structure 130 all have the barrier structure pair constituted by the first sublayer 131a, the second sublayer 131b, and the third sublayer 131c. The plural sublayers 131a-131c each may not comprise dopants, or some of the sublayers 131a-131c may comprise dopants, or all of the sublayers 131a-131c comprise dopants. The dopants may comprise n-type dopants. In one embodiment, the first sublayer 131a and/or the third sublayer 131c may not comprise dopants, while the second sublayer 131b comprise n-type dopants. The concentration of the n-type dopants may be ranged between 1E17/cm³ and 1E18/cm³.

Further as shown in FIG. 1, the first semiconductor stack 110 may further comprise plural layers, e.g., contact layer (not shown) and transition layer (not shown) that are stacked from bottom to up. The contact layer can be exposed to provide electrodes thereon in the subsequent manufacturing processes of the light-emitting element. In one embodiment, each layer of the first semiconductor stack 110 may be a single bulk layer or a multiple-layers structure. In the example that each layer of the first semiconductor stack 110 is a single bulk layer, the material composition ratio may be a fixed single composition ratio or may be a gradually changed material composition ratio with the composition ratio of the group III element of the group III-V compound semiconductor gradually changed with the depth. The single bulk layer structure may comprise dopants having first conductivity type. For instance, during the growth or deposition process of the single bulk layer structure, n-type dopants are deliberately doped in the single bulk layer structure or non-deliberately doped in the single bulk layer structure, i.e., after the single bulk layer structure is formed, dopants in the previous and subsequent layers of the single bulk layer structure diffuse to the single bulk layer structure caused by temperature.

In the example that each layer in the first semiconductor stack 110 is a multiple-sublayers structure, which may comprise nitride material sublayers constituted by two different group III element composition ratios, e.g., InGaN/GaN sublayers that are alternately stacked and constituted by two different indium composition ratio. The aforementioned InGaN sublayers constituted by two different indium composition ratios may be two sublayers with deliberately doped dopants, or one sublayer is deliberately doped, and another sublayer is non-deliberately doped, or both of the sublayers are non-deliberately doped.

In another embodiment, each layer of the first semiconductor stack 110 may comprise two sublayers that are alternately stacked and have the same composition ratio with different dopant concentrations, e.g., two kinds of nitride material sublayers having the same composition ratio that are alternately stacked, one of which is a non-deliberately doped GaN sublayer (un-doped GaN sublayer) and another of which is a deliberately doped GaN sublayer (n-GaN) with n-type dopants. The material composition ratio of each of the aforementioned sublayers may also be a fixed single composition ratio or a gradually changed material composition ratio with the composition ratio of the group III element of the group III-V compound semiconductor gradually changed with the depth.

In the present embodiment, the contact layer of the first semiconductor stack 110 may be a single bulk layer, which may comprise the nitride materials of gallium nitride, aluminum allium nitride, etc. The transition layer may be a single bulk layer or a multiple-sublayers structure. In one embodiment, the transition layer is a multiple-sublayers structure which is constituted by two InGaN sublayers that are stacked with two different indium composition ratios. One of the sublayers is deliberately doped, while another sublayer is non-deliberately doped, both of which can be represented by Inₓ₄Ga₁₋ₓ₄N (0<x4≤1) and In_{y1}Ga_{1-y1}N (0≤y1<1), while x4 is ranged between 0 and 0.1, y1 is ranged between 0 and 0.05, and x4>y1. In one embodiment, the transition layer is a multiple-sublayers structure, which is constituted by two sublayers that are stacked by two nitride material sublayers having the same composition ratio but different dopant concentration, e.g., two kinds of nitride material sublayers having the same composition ratio that are alternately stacked, one of which is a non-deliberately doped GaN sublayer (un-doped GaN sublayer) and another of which is a deliberately doped GaN sublayer (n-GaN) with n-type dopants. The thickness of each of the aforementioned sublayers is ranged, e.g., between 500 angstroms and 3000 angstroms approximately, and the concentration of the n-type dopants is ranged, e.g., between 5E17 and 5E18 per cubic centimeter. In one embodiment, the n-type dopant concentration of the contact layer is greater than the n-type dopant concentration of any layer formed on/below the contact layer, and n-type dopant concentration of the contact layer may be ranged e.g., between 5E18 to 5E19 per cubic centimeter.

The second semiconductor stack 120 may comprise an electron blocking layer 121 (EBL), an interlayer 123 and a contact layer 125 that are stacked from bottom to top in detail. Another electrode may be formed on the contact layer 125. Similar to the first semiconductor stack 110, in one embodiment, each layer of the second semiconductor stack 120 may be a single bulk layer or a multiple-layers structure. In the example that each layer of the second semiconductor stack 120 is a single bulk layer structure, the material composition ratio may be a fixed single composition ratio or a gradually changed composition ratio with the composition ratio of the group III element of group III-V compound semiconductor gradually changes with depth. The single bulk layer structure may comprise dopants having the second conductivity type. For instance, during the growth or deposition process of the single bulk layer structure, p-type dopants are deliberately doped in the single bulk layer structure or non-deliberately doped in the single bulk layer structure, i.e., after the single bulk layer structure is formed, dopants in the previous and subsequent layers of the single bulk layer structure diffuse to the single bulk layer structure caused by temperature. In the example that each layer of the second semiconductor stack 120 is a multiple-sublayers structure, which may comprise two kinds of nitride material sublayers having different group III element composition ratios that are alternately stacked, e.g., AlGaN sublayers alternately stacked by two different aluminum composition ratios, such as GaN/AlGaN. The AlGaN sublayers having two different aluminum composition ratios may be two sublayers, both of which are deliberately doped with dopants or non-deliberately doped. Alternatively, one of the sublayers is deliberately doped, while another one of the sublayers is non-deliberately doped. In another embodiment, each layer of the second semiconductor stack 120 may comprise nitride material sublayers that are stacked and have the same composition ratio with two different dopant concentrations, e.g., nitride material sublayers that are alternately stacked and have the same composition ratio and constituted by one non-deliberately doped AlGaN (un-doped AlGaN) sublayer and one AlGaN (p-AlGaN) sublayer deliberately doped by p-type dopants. Similarly, the material composition ratio of each of the sublayers may be a fixed single composition ratio or a gradually changed composition ratio with composition ratio of the group III element of the group III-V compound semiconductor gradually changes with depth.

In one embodiment, the electron blocking layer 121 may be single bulk layer structure or a multiple-sublayers structure. In an example that the electron blocking layer 121 is a single bulk layer structure, the material composition ratio may be a fixed single composition ratio or a gradually changed composition ratio with composition ratio of the group III element of the group III-V compound semiconductor gradually changes with depth. The single bulk layer structure may comprise dopants having the second conductivity type, e.g., during the growth or deposition process of the single bulk layer structure, p-type dopants are deliberately doped in the single bulk layer structure or non-deliberately doped in the single bulk layer structure, i.e., after the single bulk layer structure is formed, dopants in the previous and subsequent layers of the single bulk layer structure diffuse to the single bulk layer structure caused by temperature. In other embodiment, the electron blocking layer 121 may be a codoping structure comprising p-type dopants and n-type dopants at the same time.

The electron blocking layer 121 comprises materials with higher energy band gap, such as the materials with the energy band gap higher than the energy band gap of the active structure 130 (e.g., aluminum-containing group V semiconductor material), such as p-type AlGaN to block electron overflow phenomenon. In the example that the electron blocking layer 121 is a multiple-sublayers structure, which comprises nitride material sublayers that are alternately stacked and have two different group III element composition ratios, e.g., AlGaN/GaN sublayers that are alternately stacked and have two different aluminum composition ratios. The AlGaN sublayers having two different aluminum composition ratios may be two sublayers, both of which are deliberately doped with dopants or non-deliberately doped. Alternatively, one of the sublayers may be deliberately doped, while another one of the sublayers may be non-deliberately doped. In another embodiment, the electron blocking layer 121 may comprise nitride material sublayers that are stacked and have the same composition ratio with two different dopant concentrations, e.g., nitride material sublayers that are alternately stacked and have the same composition ratio and constituted by one non-deliberately doped AlGaN (un-doped AlGaN) sublayer and one AlGaN (p-AlGaN) sublayer deliberately doped by p-type dopants. Similarly, the material composition ratio of each of the sublayers may be a fixed single composition ratio or a gradually changed composition ratio with the composition ratio of the group III element of the group III-V compound semiconductor gradually changes with thickness.

In the present embodiment, the electron blocking layer 121 is a single layer structure, which can be represented by Alₓ₅Ga₁₋ₓ₅N (0≤x5≤1) and x5 is ranged between 0.1 and 0.05. The electron blocking layer 121 may be formed by the same or similar processes for forming the first semiconductor stack 110, the active structure 130 and the second semiconductor stack 120. The contact layer 125 of the second semiconductor stack 120 may be a single bulk layer with the material composition comprising GaN, InGaN, or AlGaN. The contact layer 125 may be deliberately doped by p-type dopants, deliberately doped by n-type dopants, or a co-doped structure comprising p-type dopants and n-type dopants. The interlayer 123 may be a single bulk layer or a multiple-sublayers structure. In one embodiment, the interlayer 123 is a multiple-sublayers structure, which is constituted by AlGaN sublayers that are stacked with two different aluminum composition ratios. The two sublayers are deliberately doped, both of which can be represented by Alₓ₆Ga₁₋ₓ₆N (0≤x6≤1) and Al_{y2}Ga_{1-y2}N (0≤y2≤1) respectively. For instance, x6 is ranged between 0 and 0.05, and y2 is ranged between 0.05 and 0.2. In the interlayer 123, the p-type dopant concentration is less than the p-type dopant concentration of the electron blocking layer 121 to enhance current spreading. For example, the p-type dopant concentration of the electron blocking layer 121 is ranged between 5E19/cm³ and 5E20/cm³. The p-type dopant concentration of the contact layer 125 is ranged between 5E18/cm³ and 5E20/cm³ or greater than 1E20/cm³. The p-type dopant concentration of the interlayer 123 may be ranged between 1E19/cm³ and 1E20/cm³. In another embodiment, the thickness of the contact layer 125 is ranged, e.g., between 30 angstroms and 100 angstroms, the thickness of the interlayer 123 is ranged, e.g., between 12 nm and 240 nm, and the thickness of the electron blocking layer 121 is ranged, e.g., between 100 angstroms and 500 angstroms. In another embodiment, the thickness of the contact layer 125 may be determined to be ranged between 1800 angstroms and 2000 angstroms, and the thickness of the interlayer 123 is ranged, e.g., between 1000 angstroms and 1300 angstroms, the thickness of the electron blocking layer 121 is ranged, e.g., between 200 angstroms and 400 angstroms.

The second semiconductor stack 120 may further comprise a hole supply structure disposed between the interlayer 123 and the contact layer 125. The hole supply structure may comprise a plurality of sublayers, such as a hole blocking layer and a hole well layer from bottom to top. The energy band gap of the hole blocking layer is greater than the energy band gap of the hole well layer. By means of the spontaneous polarization and bias polarization of the two layers, a two-dimensional hole gas (2DHG) is generated in the hole well layer near the interface between the hole blocking layer and the hole well layer. The injected current distribution can be improved by the high conductivity of the two-dimensional hole gas. The semiconductor structure 100 may also comprise a pre-strain stack 150 disposed between first semiconductor stack 110 and active structure 130 to provide further strain buffer. The pre-strain stack 150 may also comprise a plurality of sublayers, and each of the sublayers may be a single bulk layer or further comprise a multiple-sublayers structure. In the example that each of the sublayers of the pre-strain stack 150 is a single bulk layer structure, the material composition ratio may be a fixed composition ratio or a gradually changed composition ratio with the composition ratio of the group III element of the group III-V compound semiconductor changing with the depth. The pre-strain stack 150 comprises InGaN, and the composition ratios of In and Ga gradually changes. In the example that each of the sublayers of the pre-strain stack 150 is a multiple-sublayers structure, it may comprise nitride material sublayers that are stacked and have two different composition ratios of group III element, which may comprise a non-deliberately doped GaN (un-doped GaN) sublayer and an InGaN (n-InGaN) sublayer deliberately doped by n-type dopants, or two non-deliberately doped sublayers (GaN/InGaN).

In one embodiment, the pre-strain stack 150 comprises a plurality of first sublayers 151 and a plurality of second sublayers 153 that are alternately stacked. As shown in FIG. 1, the first sublayers 151 each and the second sublayers 153 each comprise nitride materials such as InGaN or GaN that are non-deliberately doped respectively. The thickness of each of first sublayers 151 or the thickness of each of the second sublayers 153 is less than the thickness T1 of each of the group III nitride barrier layer 131. The thickness of each of the first sublayers 151 is ranged, e.g., between 10 angstroms and 100 angstroms. For instance, the thickness of each of the first sublayers 151 may be 46 angstroms, 50 angstroms or 60 angstroms. The thickness of each of the second sublayers 153 is ranged, e.g., between 10 angstroms and 50 angstroms. For instance, the thickness of each of the second sublayers 153 may be 24 angstroms, 25 angstroms or 30 angstroms. It is noted that the total number of cycles of the first sublayers 151 and the second sublayers 153 specifically stacked in the pre-strain stack 150 is, e.g., 10 cycles to 50 cycles respectively, such as 25 or 35 cycles.

Therefore, the semiconductor structure 100 can emit light with the wavelength of red light by gallium nitride based material and have good light-emitting efficiency and light-emitting intensity in accordance with an embodiment of the present disclosure. In addition, persons skilled in the art should easily understand that the arrangement of at least one aluminum-containing cap layer 140 is not a limitation, and the aluminum-containing cap layer 140 may also adjusted to cover any one layer, any two layers, or each of group III nitride quantum well layer 133 in accordance with actual needs rather than being disposed on the second group III nitride quantum well layer 133 as shown in FIG. 1.

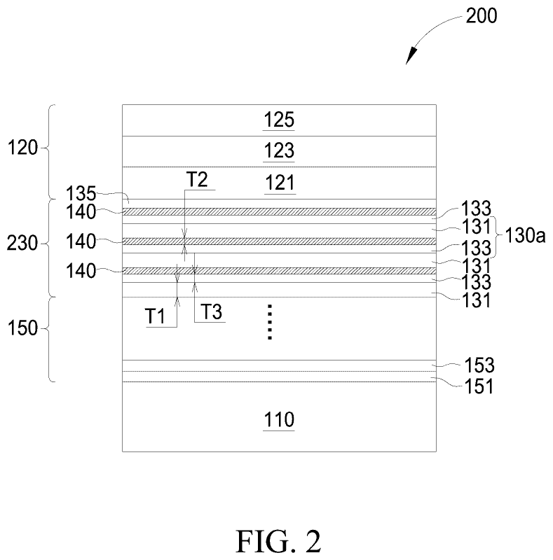

Other embodiments or its variations of the disclosed semiconductor structure will be further described below. In order to simplify the description, the following description mainly describes the differences between the embodiments each, and will not repeat the same contents. In addition, the same components in each embodiment of the present disclosure are labeled with the same numbers to facilitate referencing each of the embodiments. FIG. 2 is a schematic view of a semiconductor structure 200 in accordance with an embodiment of the present disclosure. The semiconductor structure 200 is basically the same as the semiconductor structure 100 described in the previous embodiment, and the same content will not be repeated again.

The main difference between the semiconductor structure 200 described in the present embodiment and the semiconductor structure 100 described in the aforementioned embodiment is that the semiconductor structure 200 comprises a plurality of aluminum-containing cap layers 140 covering each of the group III nitride quantum well layers 133 respectively, and each of the aluminum-containing cap layers 140 is disposed below each of the group III nitride barrier layer 131 or below the top barrier layer 135 respectively. Specifically, as shown in FIG. 2, a plurality of aluminum-containing cap layers 140 is provided in the active structure 230. Each of the aluminum-containing cap layer 140 is sandwiched between one of the group III nitride quantum well layers 133 and one of the group III nitride barrier layers 131, and is sandwiched between one of the group III nitride quantum well layers 133 and the top barrier layer 135. With this arrangement, the aluminum-containing cap layer 140 can cover each of the group III nitride quantum well layers 133 and provide strain compensation, thus improving the strain effect and reducing the structural defects of the multiple-layers quantum well structure in the active structure 230. In the meantime time, the aluminum-containing cap layer 140 can also serve as a protective layer for each of the group III nitride quantum well layers 133, blocking the elements (such as indium) of the group III nitride quantum well layer 133 generated in a low temperature environment from escaping when the group III nitride barrier layer 131 or the top barrier layer 135 are required to be formed in the high temperature manufacturing processes, so as to maintain the indium content of the group III nitride quantum well layer 133 and make indium evenly distributed. Furthermore, in the present embodiment, the thickness T1 of each of the group III nitride barrier layers 131 may also be thinned to be ranged between 200 angstroms and 550 angstroms, or between 250 angstroms and 340 angstroms, such as 260 angstroms, 270 angstroms or 340 angstroms. Alternatively, in another embodiment, the aluminum content of the group III nitride barrier layer 131 may also be increased by reducing the epitaxial growth pressure or the growth rate, so that the thickness T1 of the group III nitride barrier layer 131 may be further thinned to be ranged between 50 angstroms and 150 angstroms. For instance, the thickness T1 of the group III nitride barrier layer 131 may be 50 angstroms, 100 angstroms, or 150 angstroms in the present embodiment.

Persons skilled in the art can easily understand that, in addition to additionally providing multiple layers of aluminum-containing cap layers 140 in the active structure 230, the detailed features, the material selections, or the thickness of the first semiconductor stack 110, the second semiconductor stack 120 and/or the pre-strain stack 150 of the semiconductor structure 200, may be basically the same with the semiconductor structure 100 described in the aforementioned embodiment.

Thus, it is not repeated hereunder. As a result, by means of providing the additional multiple layers of the aluminum-containing cap layer 140 which provides strain compensation for the multiple quantum well structure and is served as a protective layer in the active structure 230, the strain effect is effectively improved and the structural defect of the active structure 230 is reduced. In the meantime, the recombination efficiency of carriers in the active structure 230 is improved, thus improving the light-emitting efficiency and light-emitting intensity. Under this circumstance, the semiconductor structure 200 of the present embodiment of the present disclosure can also emit red light with the wavelength based on gallium nitride material and have good light-emitting efficiency and light-emitting intensity.

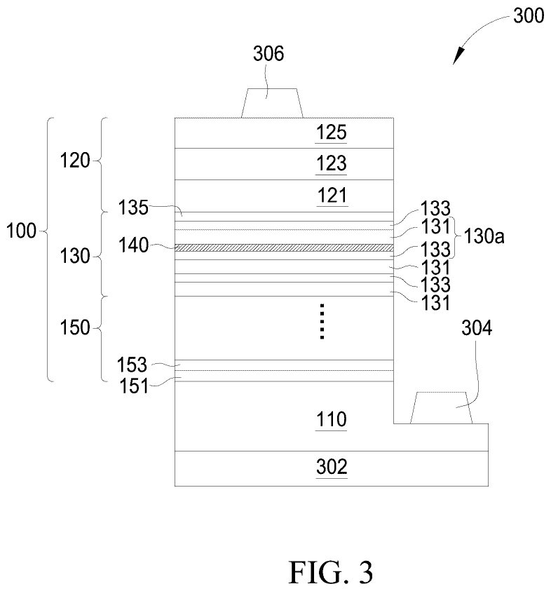

According to the aforementioned embodiments of the present disclosure, the semiconductor structures of the present disclosure (such as the semiconductor structures 100, 200 described in the aforementioned embodiments) can emit red light with the wavelength based on gallium nitride material and have good light-emitting efficiency and light-emitting intensity. In the meantime, the manufacturing processes of the semiconductor structure can be effectively simplified and the manufacturing cost can be significantly reduced. It also benefits being applied to application in various appropriate light-emitting elements, such as micro light-emitting diode, mini light-emitting diode, quantum dot light emitting diode (QLED/QDLED), or nano wire LED, after being integrated in the back-end processes. In addition, the light-emitting elements can be further manufactured to an appropriate light-emitting device by appropriate packaging process, so the light-emitting device can follow the power saving and miniaturization tend. FIGS. 3 through 5 are cross-sectional schematic views of a light-emitting element 300, a light-emitting device 310, and a perspective schematic view of a display device 320 respectively in accordance with the embodiments of the present disclosure. Among them, the light-emitting element 300 comprises the semiconductor structure 100 described in the aforementioned embodiment.

First, as shown in FIG. 3, the light-emitting element 300 comprises a semiconductor structure 100, a first electrode 304, and a second electrode 306. A light-emitting surface of the semiconductor structure 100 may have a patterned structure (not shown), so the light emitted from the semiconductor structure 100 can be refracted or reflected by the patterned structure, therefore improving the brightness of the light-emitting element 300. The semiconductor structure 100 comprises a first semiconductor stack 110 having the first conductivity type (e.g., n-type), a second semiconductor stack 120 having the second conductivity type (e.g., p-type), an active structure 130, and one of the aluminum-containing cap layers 140. The components labeled with the same numbers are basically the same as those described in the aforementioned embodiments, and it is not repeated hereunder. Persons skilled in the art can easily understand that though the light-emitting element 300 is exemplified by the semiconductor structure 100 described in the aforementioned embodiment. Considering the actual device requirements, the light-emitting element (not shown) may comprise the semiconductor structure 200 described in the aforementioned embodiment. In other embodiments, the light-emitting element may optionally comprise a substrate. The substrate may comprise a growth substrate used in growing the semiconductor structure 100, such as a silicon substrate, a silicon-on-insulator (SOI) substrate, a gallium nitride substrate, or a sapphire substrate. The semiconductor structure 100 epitaxially grown on the growth substrate may be attached to a carrier under wafer transferring processes, and then manufactured to be the light-emitting element 300 in the subsequent processes. The carrier may comprise a silicon substrate, a glass substrate, or a sapphire substrate.

In the present embodiment, as shown in FIG. 3, partial surface of the first semiconductor stack 110 is exposed rather than covered by the active structure 130 and the second semiconductor stack 120. On the other hand, the first electrode 304 is disposed on the aforementioned partial surface of the first semiconductor stack 110 and electrically connected thereto, while the second electrode 306 is disposed on the second semiconductor stack 120 and is electrically connected thereto. In addition, the first electrode 304 and/or the second electrode 306 may be further electrically connected to an external power source (not shown) or other electronic components (not shown) to transmit current. At this time, the light-emitting element 300 may be called a lateral (horizontal) type light-emitting element, and two electrodes are disposed on the same side of the semiconductor structures 100, 200 respectively. In another embodiment, the first electrode 304 may be disposed on another side of the first semiconductor stack 110 opposite to the active structure 130, i.e., the side where the light-emitting surface disposed of the semiconductor structure 100, while the second electrode 306 may be disposed on the second semiconductor stack 120. At this time, the first electrode 304 and the second electrode 306 are disposed on opposing sides of the semiconductor structures 100, 200. Such light-emitting element may be called a vertical type light-emitting element. In one embodiment, an additional transparent conductive layer (not shown) may be provided between the second electrode 306 and the second semiconductor stack 120, and an additional patterned insulating layer (not shown) may be provided between the transparent conductive layer and the second semiconductor stack 120, and/or between the first electrode 304 and the first semiconductor stack 110 to block current. In another embodiment, the first electrode 304 and/or the second electrode 306 may comprise metallic materials, such as chromium (Cr), gold (Au), aluminum (Al), copper (Cu), silver (Ag), Tin (Sn), nickel (Ni), rhodium (Rh), platinum (Pt), germanium gold nickel (GeAuNi), titanium (Ti), beryllium gold (BeAu), germanium gold (GeAu) or zinc gold (ZnAu). Further, the first electrode 304 and the second electrode 306 may comprise a single-layer structure or a multiple-layers structure, such as Ti/Au, Ti/Al, Ti/Pt/Au, Cr/Au, Cr/Pt/Au, Ni/Au, Ni/Pt/Au, Ni/Al/Ti/Au, Cr/Ti/Al/Au, Cr/Al/Ti/Au, Cr/Al/Ti/Pt, Cr/Al/Cr/Ni/Au or a combination of the above. The transparent conductive layer may comprise a transparent conductive oxide or a light-transmissive thin metal. The transparent conductive oxide may comprise indium tin oxide (ITO), indium oxide (InO), tin oxide (SnO), cadmium tin oxide (CTO), Antimony tin oxide (ATO), aluminum zinc oxide (AZO), zinc tin oxide (Zn₂SnO₄, ZTO), gallium doped zinc oxide (GZO), tungsten doped indium oxide (IWO), zinc oxide (ZnO) or indium zinc oxide (IZO), and the thin metal may comprise chromium, gold, aluminum, copper, silver, tin, nickel, rhodium, platinum or titanium.

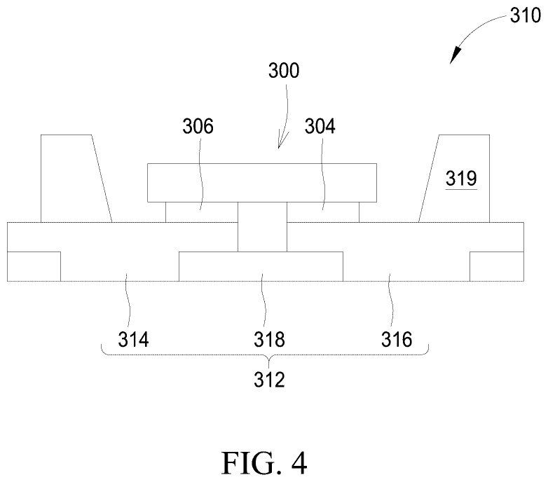

Next, FIG. 4 is a schematic view of a light-emitting device 310 in accordance with an embodiment of the present disclosure. The light-emitting element 300 of the aforementioned embodiment is mounted on a package substrate 312 in a flip chip form with the first electrode 304 and the second electrode 306 are respectively connected with the first pad 314 and the second pad 316 of the package substrate 312. The first pad 314 and the second pad 316 are electrically insulated by an insulating portion 318 comprising insulating material. In flip-chip form mounting, the side of the first semiconductor stack 110 opposite to the electrode is set upward to be the main light extraction surface. In order to increase the light extraction efficiency of the light-emitting device 310, a reflective structure 319 may be provided in the proximity of the light-emitting element 300. In another embodiment, the light-emitting element 300 may be structured in a vertical type light-emitting element to be mounted on the first pad 314 of the package substrate 312. The first electrode 304 is electrically connected with the first pad 314, and the second electrode 306 is electrically connected with the second pad 316 via a lead wire (not shown).

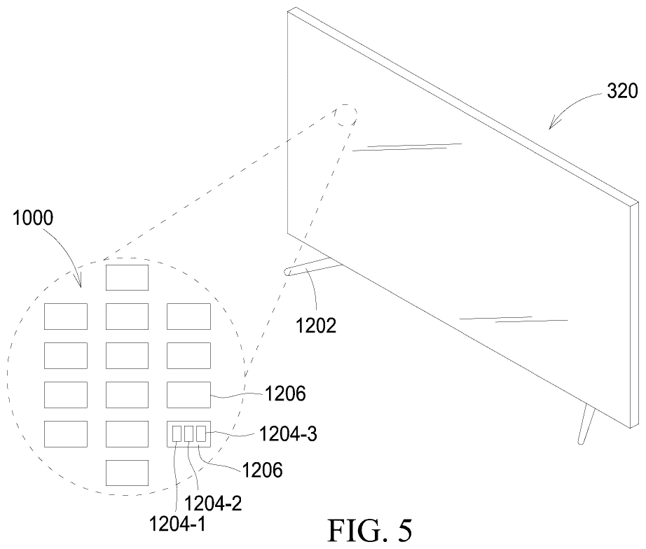

Then, as shown in FIG. 5, a display device 320 is supported by a bracket 1202 and comprises a plurality of light-emitting devices 1000. The light-emitting device 1000 comprises a plurality of light-emitting elements 1204-1, each of which is structured similar to the structure of the light-emitting element 300 described in the aforementioned embodiments each. The light-emitting element 1204-1 and other light-emitting elements that emit light with different colors, e.g., the light-emitting element 1204-2 emitting green light and the light-emitting element 1204-3 emitting blue light, may be grouped to a light-emitting element groups 1206, so that each of the light-emitting element group 1206 of the light-emitting device 1000 can constitute each pixel of the display device 320, and each of the light-emitting elements 1204-1, 1204-2, and 1204-3 of the light-emitting element group 1206 constitutes a sub-pixel of the pixel. Therefore, by the semiconductor structure 100 having indium gallium nitride based material, the materials of the light-emitting elements 1204-1, 1204-2, and 1204-3 are similar (all of them are made by group III nitride materials), so that they can be more easily integrated in the manufacturing processes. Further, the light-emitting elements 1204-1, 1204-2, and 1204-3 can also be more consistent in optoelectrical characteristics, facilitating the application end easily adjusting the driving and the controlling of the display device 320.

Therefore, the light-emitting element 300 having the semiconductor structure 100 having the indium gallium nitride based material of the present disclosure can emit red light with specific wavelength and have good light-emitting efficiency and good light-emitting intensity. In particular, when light-emitting element 300 structured in the form of micro LEDs is applied in the display devices, by the reason that the material used in the light-emitting element 300 emitting red light and the material used in light-emitting elements (not shown) emitting green light and blue light respectively are all group III nitride materials, they can be more consistent in optoelectrical characteristics, facilitating the application end easily adjusting the driving and the controlling of the display device. In one embodiment, the light-emitting element 300 may have a miniaturized size of 24 μm×54 μm, and it can obtain good external quantum efficiency (EQE), smaller blue shift phenomenon and emit light with the wavelength greater than 600 nm under the condition of lower current density driving.

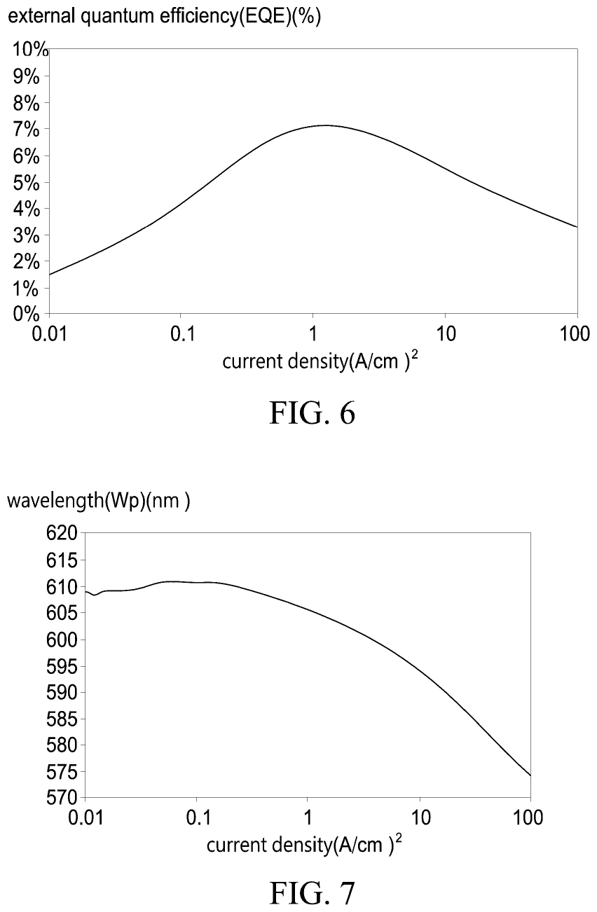

FIG. 6 through FIG. 8 respectively show the curve chart of the external quantum efficiency curve, the curve chart of the wavelength (Wp), and the curve chart of the initiating voltage (Vf) of the light-emitting element 300 changing with the current density in accordance with the embodiment of the present disclosure. FIG. 9 is a curve chart showing the wavelength versus the relative light-emitting intensity of the light-emitting element 300 under different current densities in accordance with the embodiment of the present disclosure.

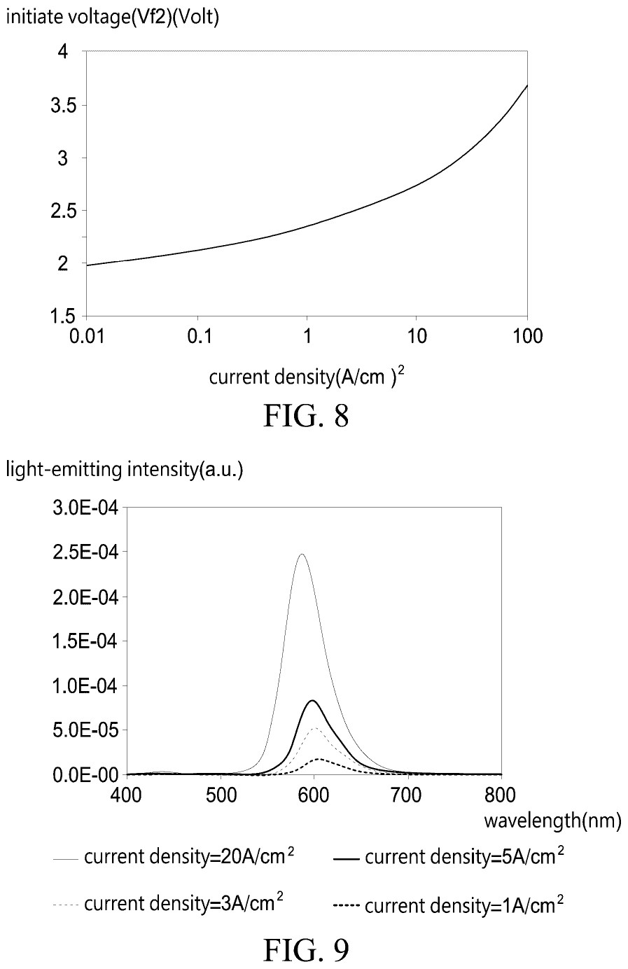

Firstly, as shown in FIG. 6 through FIG. 8, the light-emitting element 300 may have a miniaturized size of 24 μm×54 μm. When the light-emitting element 300 is operated by 0.01-1.3 current density (A/cm²), it can meet the requirement of emitting light with the wavelength greater than 600 nm (shown in FIG. 7). In particularly, when the current density is operated between 1.2 (A/cm²) to 1.3 (A/cm²), the external quantum efficiency of the light-emitting element 300 is not less than 7%, e.g., between 7% and 8% approximately (as shown in FIG. 6), and when the light-emitting element 300 is operated in the operating voltage between 2.4 (V) to 2.5 (V) approximately as shown in FIG. 8, the light-emitting element 300 can compete with traditional red light-emitting devices with the same size having group III phosphide materials. Next, as shown in FIG. 9, when the light-emitting element 300 is operated by the current density not greater than 20 (A/cm²), e.g., 20 (A/cm²), 5 (A/cm²), 3 (A/cm²), and 1 (A/cm²), the light-emitting element 300 still emits light with the wavelength of 600 nm approximately without emitting light of other colors.

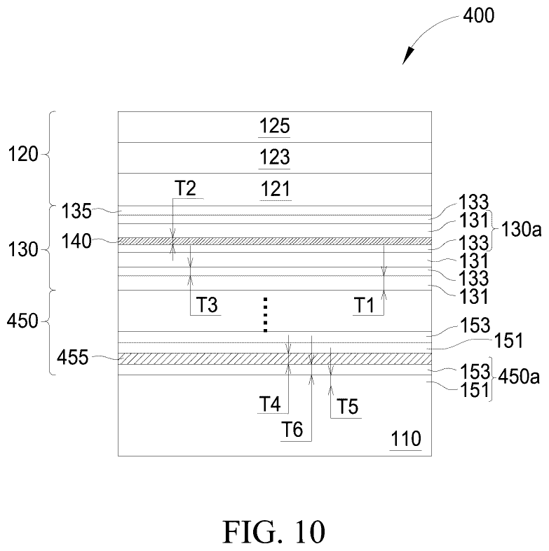

FIG. 10 is a schematic view of a semiconductor structure 400 in accordance with an embodiment of the present disclosure. The structure of the semiconductor structure 400 is basically the same with the structure of the semiconductor structure 100 described in the aforementioned embodiments, and the similarities are not repeated hereunder. The main difference between the semiconductor structure 400 of the present embodiment and the semiconductor structure 100 of the aforementioned embodiment is that it further comprises one aluminum-containing interlayer 455 disposed in the pre-strain stack 450 or disposed on the pre-strain stack 450.

In detail, the pre-strain stack 450 comprises one or plural pre-strain stack pairs 450a, each of which comprises a first sublayer 151 and a second sublayer 153. When the pre-strain stack pairs 450a are plural, each of which is formed by a stack constituted by the first sublayers 151 and the second sublayers 153 that are alternately stacked. In one embodiment, the energy barrier of the first sublayer 151 in the pre-strain stack 450 is greater than the energy barrier of the second sublayer 153, and the energy barrier of the aluminum-containing interlayer 455 is greater than the energy barrier of the first sublayer 151 and the second sublayer 153 respectively. The first sublayer 151 of the pre-strain stack 450 may comprise Al_{y4}Ga_{1-y4}N materials, wherein y4 is ranged between 0 and 1, or between 0 and 0.5, while the second sublayer 153 of the pre-strain stack 150 may comprise In_{y5}Ga_{1-y5}N materials, wherein y5 is ranged between 0 and 1, or between 0.01 and 0.3. The first sublayer 151 and/or the second sublayer 153 may be deliberately doped or non-deliberately doped material layer. The aluminum-containing interlayer 455 may comprises Al_{y3}Ga_{1-y3}N material, wherein 0≤y3≤1, or 0.5≤y3≤1.

The aluminum-containing interlayer 455 is disposed on the second sublayer 153 of the pre-strain stack 450. In one embodiment, one pre-strain stack pair 450a comprises the aluminum-containing interlayer 455. In the growth direction of the semiconductor structure 100, the first sublayer 151 of the pre-strain stack pair 450a is formed on the second sublayer 153, and the aluminum-containing interlayer 455 is disposed between the second sublayer 153 and the first sublayer 151. In one embodiment, one of the pre-strain stack pair 450a comprises the aluminum-containing interlayer 455. In the growth direction of the semiconductor structure 100, the second sublayer 153 of the pre-strain stack pair 450a is formed on the first sublayer 151, and the aluminum-containing interlayer 455 is disposed on the second sublayer 153, i.e., disposed on one of the pre-strain stack pairs 450a. In one embodiment, as shown in FIG. 10, the pre-strain stack 450 comprises a plurality of pre-strain stack pairs 450a, and the aluminum-containing interlayer 455 may be disposed on any one of the pre-strain stack pairs 450a of the pre-strain stack 450 and adjacent to the first sublayer 151 of the next pre-strain stack pair 450a. In another embodiment, the aluminum-containing interlayer 455 may be disposed on the last pre-strain stack pair 450a of the pre-strain stack 450 and adjacent to the group III nitride barrier layer 131 of the first set of the quantum well structure pairs 130a. The aluminum-containing interlayer 455 has high density. The thickness T4 of the aluminum-containing interlayer 455 may be adjusted in accordance with the aluminum content of the composition ratio of the aluminum-containing interlayer 455. In one embodiment, the aluminum content of the aluminum-containing interlayer 455 may be increased, so that the thickness T4 of the aluminum-containing interlayer 455 is thinner than the thickness of the aluminum-containing interlayer 455 with lower aluminum content. The thickness T4 of the aluminum-containing interlayer 455 is ranged approximately between 5 angstroms and 50 angstroms. The thickness T5 of any one of the first sublayers 151 or the thickness T6 of any one of the second sublayers 153 may be less than the thickness T1 of the group III nitride barrier layer 131 of the active structure 130. The thickness T5 of any one of the first sublayer 151 is ranged between 30 angstroms and 100 angstroms. For instance, the thickness T5 of any one of the first sublayer 151 may be 46 angstroms or 60 angstroms, and the thickness T6 of any one of the second sublayers 153 is ranged between 10 angstroms and 50 angstroms. For instance, the thickness T6 of any one of the second sublayers 153 may be 24 angstroms, 25 angstroms, or 30 Angstrom.

In some embodiments, the first sublayer 151 or the second sublayer 153 may be the first layer of the pre-strain stack 450. When the first sublayers 151 and second sublayers 153 are alternately stacked, the first sublayer 151 or the second sublayer 153 may be served as the first layer. Similarly, the first sublayer 151 or the second sublayer 153 may be served as the last layer. When the total number of cycles of the stacked first sublayer 151 and the second sublayer 153 is ranged between 10 cycles to 50 cycles. For instance, the total number of cycles of the stacked first sublayer 151 and the second sublayer 153 may be 25 cycles or 35 cycles, the pre-strain stack 450 may comprise 25 or 35 pre-strain stack pairs 450a. In one embodiment, when the semiconductor structure 400 comprises plural aluminum-containing interlayers 455, each of the aluminum-containing interlayers 455 may be respectively disposed on the second sublayer 153 of the pre-strain stack pairs 450a, or disposed on the second sublayer 153 of each of the pre-strain stack pairs 450a, so that each of the aluminum-containing interlayer 455 is respectively disposed on each of the second sublayers 153 and the adjacent one of the first sublayers 151.

Persons skilled in the art can easily understand that, in addition to additionally providing at least one aluminum-containing interlayer 455 in the pre-strain stack 450, the detailed features, the material selection, and the thickness of the first semiconductor stack 110, the second semiconductor stack 120 and/or the active structure 130 of the semiconductor structure 400 are all basically the same as those of the semiconductor structure 100 described in the aforementioned embodiment, and they are not repeated hereunder. Therefore, the semiconductor structure 400, which is made by gallium nitride based material in accordance with an embodiment of the present disclosure, can still emit light with red light wavelength and have good light-emitting efficiency and light-emitting intensity. It is noted that in the semiconductor structure 400, the pre-strain stack 450 is disposed between the first semiconductor stack 110 and the active structure 130 to alleviate the strain caused by the lattice differences between the first semiconductor stack 110 and the active structure 130. The second sublayer 153 of the pre-strain stack 450 comprises InGaN material, and the first sublayer 151 may comprise GaN material. By means of adjusting the indium content of the second sublayer 153, e.g., increasing the indium content, the lattice constant of the pre-strain stack 450 can match the lattice constant of the active structure 130 to reduces the impact of the strain on the active structure 130. Due to the strain caused by different lattice constants caused by different materials of the first sublayer 151 and the second sublayer 153 in the pre-strain stack 450, and due to the thermal influence caused in the epitaxial growth temperature when forming the pre-strain stack 450, indium may thermally escape from the composition of the second sublayer 153 when the second sublayer 153 is grown, therefore the indium content of the second sublayer 153 may not be increased as expected. In the present embodiment, by means of providing the aluminum-containing interlayer 455 between the adjacent second sublayer 153 and the first sublayer 151 in the pre-strain stack 450, the indium cannot easily thermally escape from the composition of the second sublayer 153, thus increasing the indium content of the pre-strain stack 450 and facilitating the lattice constant of the pre-strain stack 450 increasing to be closer to the lattice constant of the active structure 130 to further enhance the strain compensation effect of the pre-strain stack 450 to the active structure 130. Therefore, the quantum confined Stark effect (QCSE) caused by strain can be reduced to further reduce the derived blue shift phenomenon and further reduce the half-maximum width of the spectrum generated by the semiconductor structure 400.

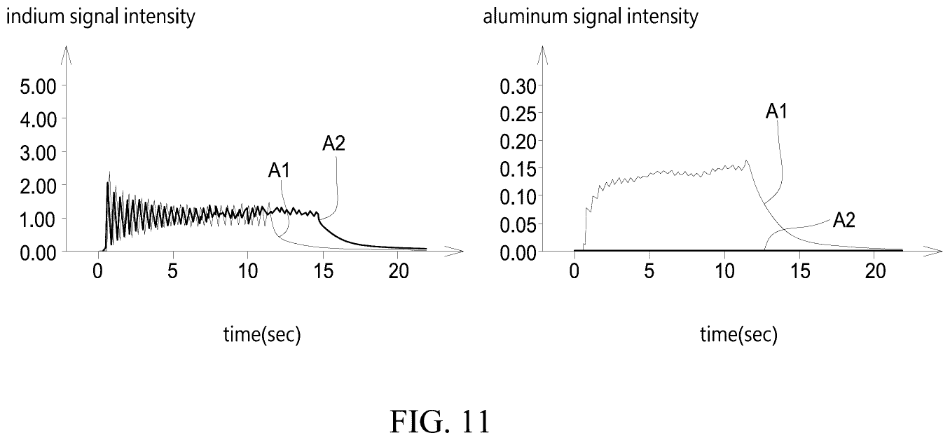

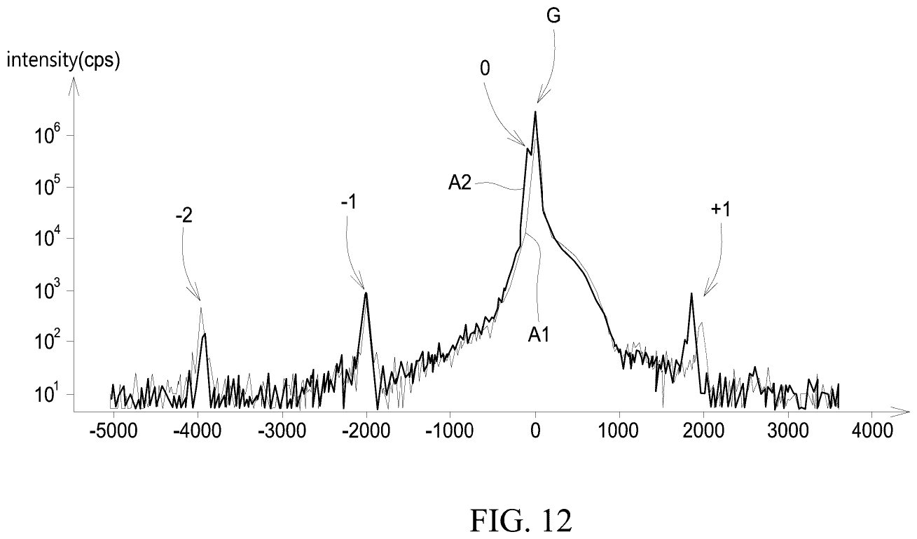

FIGS. 11, 12 are schematic views of the analysis results of the destructive physical analysis (DPA) and X-Ray Diffraction Analysis (XRD) of an embodiment and a comparative embodiment under the same epitaxial conditions in accordance with the present disclosure. In the present embodiment, the aluminum-containing interlayer 455 of the pre-strain stack 450 (e.g., comprising 25 cycles of first sublayers 151, 25 cycles of the second sublayers 153, and the corresponding one of the aluminum-containing interlayers 455 on each of the second sublayers 153) is provided on the first semiconductor stack 110, while in the comparative embodiment, the pre-strain stack 150 is void of the aluminum-containing interlayer 455 (e.g., comprising 25˜35 cycles of first sublayers 151, 25˜35 cycles of the second sublayers 153). In the pre-strain stack 450 of the present embodiment and the pre-strain stack 150 of the comparative embodiment, the material of the first semiconductor stack 110 is GaN. The material of the first sublayer 151 is GaN, the material of the second sublayer 153 is InGaN, and the material of the aluminum-containing interlayer 455 is AlN. Firstly, as shown on the left side of FIG. 11, because the pre-strain stack 450 is provided with the aluminum-containing interlayer 455, the aluminum content is shown in the analysis chart A1 of the pre-strain stack 450 of the present embodiment, while in the comparative embodiment, because the pre-strain stack 150 is void of aluminum-containing interlayer 455, the aluminum content is zero in the analysis chart A2 of the pre-strain stack 150 (as shown on the right part of FIG. 11). The indium content shown in the analytical chart A1 of the pre-strain stack 150 is also higher than the indium content shown in the analysis chart A2 of the pre-strain stack 150. Because the pre-strain stack 450 of the present embodiment has the aluminum-containing interlayer 455, the indium of the second sublayers 153 is difficult to thermally escape, thus maintaining the indium content of the second sublayer 153 that is predetermined in the epitaxial setting (shown on the left part of FIG. 11). On the other hand, as shown in FIG. 12, in the analysis chart A2 of the pre-strain stack 150, there are XRD signals of the GaN material contained in the first semiconductor stack 110 and periodic XRD signals of the GaN material and the InGaN material contained in the first sublayer 151 and the second sublayer 153 respectively. The 0th-order main peak position of the InGaN/GaN material contained in the second sublayer 153/first sublayer 151 is adjacent to the peak signal G of the GaN material contained in the first semiconductor stack 110. In the XRD signal of the pre-strain stack 450 having the aluminum-containing interlayer 455, it only shows the GaN signal of the first semiconductor stack 110 without the InGaN signal at the 0th-order main peak position. Because the 0th-order main peak signal of InGaN overlaps the peak signal G of the GaN material due to the strain compensation effect caused by the aluminum-containing interlayer 455, only the XRD peak signal G of the GaN material exists. In addition, in the analysis chart A1 of the pre-strain stack 450, the spacing defined between the −2 order satellite peak and the −1 order satellite peak and the spacing defined between the −1 order satellite peak and the +1 order satellite peak is respective greater than those shown in the analysis chart A2 of the pre-strain stack 150. It indicates that the lattice constant of the pre-strain stack 450 is greater than the lattice constant of the pre-strain stack 150, i.e., the indium content of the pre-strain stack 450 is greater than the indium content of the pre-strain stack 150. Therefore, by the analysis data of XRD and DPA, the indium content of the pre-strain stack 450 can be proved to be greater than the indium content of the pre-strain stack 150, i.e., the indium content of the second sublayer 153 in the pre-strain stack 450 is greater than the indium content of the second sublayer 153 in the pre-strain stack 150, which indicates that the lattice constant of the pre-strain stack 450 is greater than the indium constant of the pre-strain stack 150. The aforementioned analysis results can prove that by providing the aluminum-containing interlayer 455 in the superlattice structure of the pre-strain stack 450, it indeed benefits alleviating the strain in the pre-strain stack 450. In addition, the aluminum-containing interlayer 455 can make the indium of the second sublayer 153 difficult to thermally escape, thus increasing the indium content of the pre-strain stack 450 and facilitating the lattice constant of the pre-strain stack 450 to be closer to the lattice constant of the active structure 130. Therefore, it improves the strain compensation effect of the pre-strain stack 450 to the active structure 130 and alleviate the impact of strain on the active structure 130.

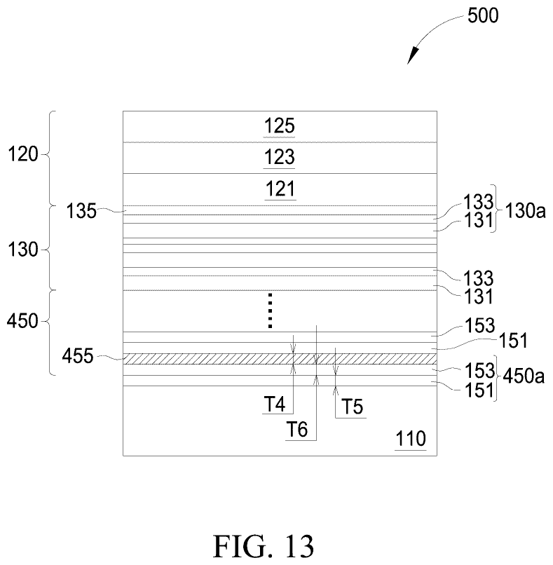

FIG. 13 illustrates a schematic view of a semiconductor structure 500 in accordance with an embodiment of the present disclosure. The structure of the semiconductor structure 500 is basically the same as the structure of the semiconductor structure 400 in the aforementioned embodiment, and the same features are not repeated hereunder. The main difference between the semiconductor structure 500 of the present embodiment and the semiconductor structure 400 of the aforementioned embodiment is that it is void of the aluminum-containing cap layer 140 in the active structure 130.

Persons skilled in the art can easily understand that, in addition to the aforementioned different features, the detailed features, the material selection and the thickness of components, such as the first semiconductor stack 110, the second semiconductor stack 120 and/or the pre-strain stack 450 of the semiconductor structure 500 are basically the same as the semiconductor structure 400 of the aforementioned embodiment, and they are not repeated hereunder. Therefore, the semiconductor structure 500 in accordance with an embodiment of the present disclosure can also emit light with red light wavelength based on gallium nitride material. Further, the aluminum-containing interlayer 455 provided in the pre-strain stack 450 can effectively enhance the strain compensation effect of the pre-strain stack 450, and XRD also shows that the superlattice constant of the pre-strain stack 450 is increased to be closer to the lattice constant of the active structure 130, thus alleviating the impact of strain on the active structure 130. In particular, when the indium content of the second sublayer 153 of the pre-strain stack 450 is significantly increased, by the strain compensation caused by the aluminum-containing interlayer 455, the strain caused by the lattice differences in the pre-strain stack 450 can be alleviated.

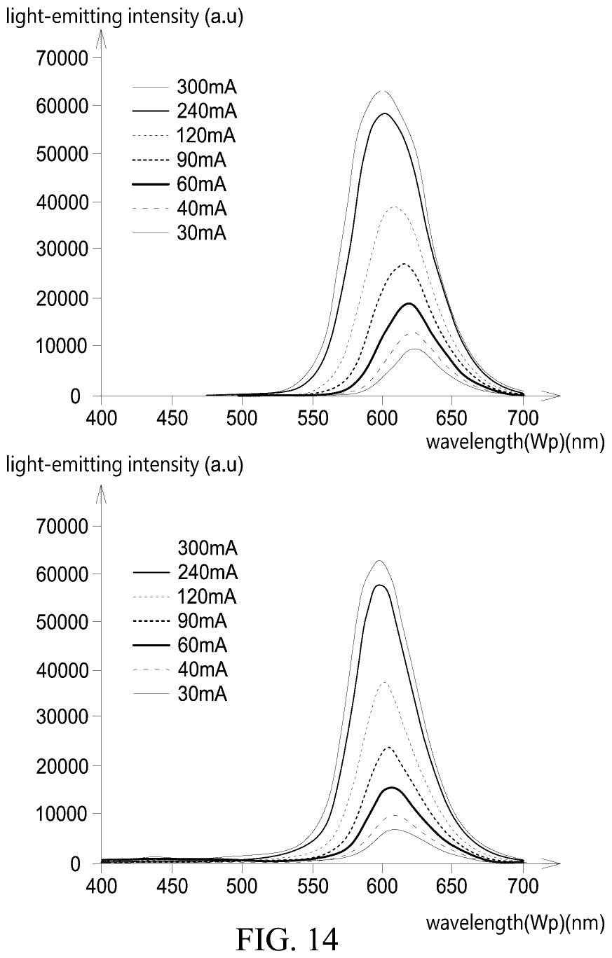

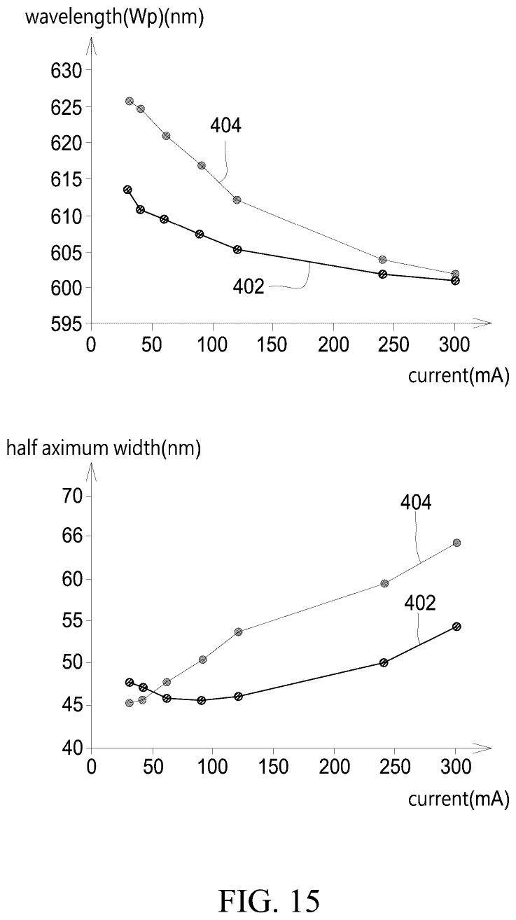

The semiconductor structure 400 and the semiconductor structure 500 of the aforementioned embodiments of the present disclosure can also be further applied to manufacture of various appropriate light-emitting elements or light-emitting devices. For example, a light-emitting element 300 similar to that shown in FIG. 3 may be manufactured, in which the semiconductor structure 100 is replaced by the semiconductor structure 400 or the semiconductor structure 500, and can emit light with the wavelength greater than 600 nm when driven by current. In addition to obtaining good external quantum efficiency, blue shift phenomenon can be alleviated and the half-maximum width of wavelength of the emitted light can be reduced. FIGS. 14, 15 respectively show the spectrum charts of a light-emitting element 402 comprising the aluminum-containing interlayer 455, such as the light-emitting element manufactured in accordance with the semiconductor structure 400 of the aforementioned embodiment, and the spectrum chart of another light-emitting element 404 of the semiconductor structure void of the aluminum-containing interlayer 455 under different currents. The spectrum charts also show the wavelength peak tendency and the half-maximum width tendency. Firstly, as shown in FIG. 14, when the driving current is increased from 30 mA to 300 mA, the peak spectrum value of the light-emitting element 404 gradually moves toward the short wavelength direction (as shown in the upper part of FIG. 14), indicating that blue shift phenomenon occurs, while the peak spectrum value of the light-emitting element 402 is basically maintained to be 600 nm and has a smaller half-maximum width (as shown at the bottom part of FIG. 14). As further shown in FIG. 15, in the same current changing interval, the blue shift of the light-emitting wavelength of the light-emitting element 404 is 23 nm approximately, while the blue shift of the light-emitting wavelength of the light-emitting element 402 is 12 nm approximately (shown at the top part of FIG. 15). On the other hand, due to the band-filling effect, the half-maximum width of the light-emitting wavelength of the light-emitting element 404 is continuously changed from 45 nm to 65 nm approximately, while the half-maximum width of the light-emitting wavelength of the light-emitting element 402 is gradually decreased from 48 nm to 45 nm approximately as the current increases, then the half-maximum width increases to 55 nm as the current further increases (as shown at the bottom part of FIG. 15). It should be noted that since the arrangement of the aluminum-containing interlayer 455 can change the strain in the pre-strain stack 450, when the current is less than 90 mA, due to the decrease of the strain, the carrier screen effect caused by the electric field can be further reduced, so that the half-maximum width of the light-emitting wavelength of the light-emitting element 402 is therefore decreased. The blue shift phenomenon of the light-emitting wavelength of the light-emitting element 402 can be further alleviated. That is, by providing the aluminum-containing interlayer 455 in the superlattice structure of the pre-strain stack 450, it can alleviate the strain in the pre-strain stack 450, and it also improves the epitaxial quality of the multiple quantum well structures of the active structure 130. It also further alleviates the likely derived blue shift phenomenon of the light-emitting wavelength of the active structure 130, preventing the increasement of the half-maximum width and benefiting manufacturing various kinds of appropriate light-emitting elements or light-emitting device to achieve good operating performance.

In summary, by providing at least one aluminum-containing cap layer in the active structure of the semiconductor structure, and/or by providing at least one aluminum-containing interlayer in/on the pre-strain stack in the present disclosure, additional strain compensation and protection can be provided to the multiple quantum well structure and/or pre-strain stack to alleviate strain effect and reduce structural defects of the active structure, improving the recombination efficiency of carriers in the active structure, and further enhancing the light-emitting efficiency and light-emitting intensity of the semiconductor structure. Therefore, the semiconductor structure can be applied to various kinds of appropriate light-emitting elements e.g., micro LED or mini LED with smaller size after being integrated in the back-end processes. Further, the semiconductor structure can also be further used in manufacturing appropriate light-emitting elements or light-emitting devices under further appropriate packaging processes, so that the light-emitting elements or light-emitting devices can follow the power saving and miniaturization trend.

Although some embodiments of the present disclosure and their advantages have been described in detail, it should be understood that various changes, substitutions and alterations can be made herein without departing from the spirit and scope of the disclosure as defined by the appended claims.

What is claimed is:

1. A semiconductor structure, comprising:
a first semiconductor stack having a first conductivity type;
a second semiconductor stack having a second conductivity type;
an active structure disposed between the first semiconductor stack and the second semiconductor stack, the active structure comprising a plurality of quantum well structure pairs, each of which comprising a group III nitride barrier layer and a group III nitride quantum well layer adjacent to the group III nitride barrier layer, wherein the group III nitride barrier layer in one of the plurality of quantum well structure pairs has a thickness ranged between 200 angstroms to 550 angstroms; and
a first aluminum-containing cap layer disposed between the group III nitride barrier layer and the group III nitride quantum well layer in the one of the plurality of quantum well structure pairs;
wherein the active structure emits light with a wavelength of at least 600 nm.

2. The semiconductor structure as claimed in claim 1, wherein the group III nitride quantum well layer in the one of the plurality of quantum well structure pairs each comprises Inₓ₂GaN material, wherein x2 is ranged between 0.18 to 0.45, and the group III nitride quantum well layers in the one of the plurality of quantum well structure pairs each has a thickness ranged between 30 angstroms and 45 angstroms.

3. The semiconductor structure as claimed in claim 1, wherein the first aluminum-containing cap layer comprises Alₓ₃Ga₁₋ₓ₃N material, and 0.5≤x3≤1, the first aluminum-containing cap layer has a thickness ranged between 15 angstroms and 30 angstroms.

4. The semiconductor structure as claimed in claim 1, wherein the first aluminum-containing cap layer has a thickness less than the thickness of the group III nitride barrier layer in the one of the plurality of quantum well structure pairs.

5. The semiconductor structure as claimed in claim 1, wherein the active structure further comprises a top barrier layer, and the top barrier layer has a thickness less than the thickness of the group III nitride barrier layer in the one of the plurality of quantum well structure pairs.

6. The semiconductor structure as claimed in claim 5, further comprising a second aluminum-containing cap layer disposed between the top barrier layer and the plurality of quantum well structure pairs.

7. The semiconductor structure as claimed in claim 1, comprising a plurality of the first aluminum-containing cap layers, each of which is disposed between the group III nitride quantum well layer and the group III nitride barrier layer in each of the plurality of quantum well structure pairs.

8. The semiconductor structure as claimed in claim 1, wherein the plurality of quantum well structure pairs is provided with a quantity of 2 to 5.

9. The semiconductor structure as claimed in claim 1, further comprising:
a pre-strain stack disposed between the first semiconductor stack and the active structure, the pre-strain stack comprising a plurality of first sublayers and a plurality of second sublayers that are alternately stacked; and
an aluminum-containing interlayer disposed in the pre-strain stack and between one of the plurality of first sublayers and one of the plurality of second sublayers.

10. The semiconductor structure as claimed in claim 9, wherein the pre-strain stack comprises a plurality of pair layers, each of which is defined by one of the plurality of first sublayers and one of the plurality of second sublayers, and the plurality of pair layers is provided with a quantity of 10 to 50.

11. The semiconductor structure as claimed in claim 9, wherein the aluminum-containing interlayer comprises Al_{y3}Ga_{1-y3}N material, wherein 0.5≤y3≤1, and the aluminum-containing interlayer has a thickness ranged between 5 angstroms and 50 angstroms.

12. A semiconductor structure, comprising:
a first semiconductor stack having a first conductivity type;
a second semiconductor stack having a second conductivity type;
an active structure disposed between the first semiconductor stack and the second semiconductor stack, the active structure comprising group III nitride barrier layers and group III nitride quantum well layers that are alternately stacked;
a pre-strain stack disposed between the first semiconductor stack and the active structure, the pre-strain stack comprising a plurality of pair layers, each of the pair layers comprising a first sublayer and a second sublayer;
an aluminum-containing interlayer disposed in the pre-strain stack or on the pre-strain stack;
wherein the active structure emits light with a wavelength of at least 600 nm.

13. The semiconductor structure as claimed in claim 12, wherein the aluminum-containing interlayer comprises Al_{y3}Ga_{1-y3}N material, wherein 0.5≤y3≤1, and the aluminum-containing interlayer comprises a thickness ranged between 5 angstroms to 50 angstroms.

14. The semiconductor structure as claimed in claim 13, wherein the aluminum-containing interlayer is plural, each of which is disposed between the first sublayer and the second sublayer in each of the plurality of pair layers.

15. The semiconductor structure as claimed in claim 12, wherein the first sublayer comprises Al_{y4}Ga_{1-y4}N material, and y4 is ranged between 0 and 0.5; wherein the second sublayer comprises In_{y5}Ga_{1-y5}N material, and y5 is ranged between 0.01 and 0.3.

16. The semiconductor structure as claimed in claim 12, wherein each of the group III nitride barrier layers comprises Alₓ₁Ga₁₋ₓ₁N material, wherein 0≤x1≤0.3, and each of the group III nitride barrier layers comprises a thickness ranged between 50 angstroms and 150 angstroms.

17. The semiconductor structure as claimed in claim 15, wherein no main diffraction peak of the In_{y5}Ga_{1-y5}N material of the second sublayers exists in a X-ray diffraction analytic spectrum of the pre-strain stack.

18. The semiconductor structure as claimed in claim 12, wherein the aluminum-containing interlayer is disposed between the first sublayer and the second sublayer in one of the plurality of pair layers.
